(19) United States
(12) Patent Application Publication
(10) Pub. No.: US 2024/0057457 A1
(43) Pub. Date: Feb. 15, 2024

(54) DISPLAY APPARATUS MANUFACTURING APPARATUS AND METHOD

(71) Applicant: SAMSUNG DISPLAY CO., LTD., Yongin-si (KR)

(72) Inventors: Kwangjun KOO, Yongin-si (KR); Donghoon SHIN, Yongin-si (KR); Hoonchul RYOO, Yongin-si (KR); Kyongsik CHOI, Yongin-si (KR); Jeongmok KIM, Yongin-si (KR); Jaewoong MOON, Yongin-si (KR); Dongeon LIM, Yongin-si (KR)

(21) Appl. No.: 18/119,155

(22) Filed: Mar. 8, 2023

(30) Foreign Application Priority Data
Aug. 9, 2022 (KR) 10-2022-0099436

(51) Int. Cl. H10K 59/80; H10K 59/123

(52) U.S. Cl. CPC H10K 59/879; H10K 59/878; H10K 59/123

(57) ABSTRACT

A display apparatus manufacturing apparatus includes: a laser emitter for emitting a laser having dispersion in a short-axis direction greater than dispersion in a long-axis direction, and a laser converter for converting the laser into a converted laser having dispersion in the long-axis direction greater than dispersion in the short-axis direction.

This application claims priority to Korean Patent Application No. 10-2022-0099436, filed on Aug. 9, 2022, and all the benefits accruing therefrom under 35 U.S.C. § 119, the content of which in its entirety is herein incorporated by reference.

### BACKGROUND

### 1. Field

One or more embodiments relate to apparatuses and methods, and more particularly, to display apparatus manufacturing apparatuses and methods.

### 2. Description of the Related Art

An electronic apparatus based on mobility has been widely used. In addition to a small electronic apparatus such as a mobile phone, a tablet personal computer (“PC”) has been widely used as a mobile electronic apparatus.

Generally, in a display apparatus such as an organic light emitting display apparatus, a thin film transistor for controlling an operation of each (sub)pixel is disposed over a substrate. The thin film transistor includes a semiconductor layer, a source electrode, a drain electrode, a gate electrode, and the like. In this case, generally, the semiconductor layer includes polysilicon crystallized from amorphous silicon, and for crystallization, a laser is irradiated onto an amorphous silicon layer.

### SUMMARY

One or more embodiments include converting a laser having dispersion in the short-axis direction greater than dispersion in the long-axis direction into a laser having dispersion in the long-axis direction greater than dispersion in the short-axis direction.

However, these aspects are merely examples, and the problems to be solved by the disclosure are not limited thereto.

Additional aspects will be set forth in part in the description which follows and, in part, will be apparent from the description, or may be learned by practice of the presented embodiments of the disclosure.

According to one or more embodiments, a display apparatus manufacturing apparatus includes: a laser emitter for emitting a laser having dispersion in a short-axis direction greater than dispersion in a long-axis direction, and a laser converter for converting the laser into a converted laser having dispersion in the long-axis direction greater than dispersion in the short-axis direction.

In the present embodiments, the laser converter may include an angle converter for rotating a cross-section of the laser.

In the present embodiments, the angle converter may include a dove prism.

In the present embodiments, the laser converter may include a size converter for increasing a length in the short-axis direction of the laser and for decreasing a length in the long-axis direction of the laser.

In the present embodiments, the size converter may include a first concave lens for dispersing the laser in the short-axis direction, and a first convex lens for straightly moving the laser dispersed in the short-axis direction, where the laser may increase in length in the short-axis direction while sequentially passing through the first concave lens and the first convex lens.

In the present embodiments, the size converter may include a second convex lens for focusing the laser in the long-axis direction, and a second concave lens for straightly moving the laser focused in the long-axis direction, where the laser may decrease in length in the long-axis direction while sequentially passing through the second convex lens and the second concave lens.

In the present embodiments, the laser emitter may include a first laser emitter for emitting a first laser, and a second laser emitter for emitting a second laser, where the laser converter may include a first laser converter through which the first laser passes.

In the present embodiments, the laser converter may further include a second laser converter through which the second laser passes.

In the present embodiments, the display apparatus manufacturing apparatus may further include a path converter for converting a path of the laser or the converted laser.

In the present embodiments, the display apparatus manufacturing apparatus may further include a telescope lens for adjusting a size of a cross-section of the converted laser.

In the present embodiments, the display apparatus manufacturing apparatus may further include a homogenizer for homogenizing an energy density of a cross-section of the converted laser.

According to one or more embodiments, a display apparatus manufacturing method includes: emitting a laser having dispersion in a short-axis direction greater than dispersion in a long-axis direction; converting the laser into a converted laser having dispersion in the long-axis direction greater than dispersion in the short-axis direction; and irradiating the converted laser onto a display substrate to crystallize at least a portion of the display substrate.

In the present embodiments, the display apparatus manufacturing method may further include rotating a cross-section of the laser.

In the present embodiments, the rotating of the cross-section of the laser may include passing the laser through a dove prism.

In the present embodiments, the display apparatus manufacturing method may further include increasing a length in the short-axis direction of the laser, and decreasing a length in the long-axis direction of the laser.

In the present embodiments, the increasing of the length in the short-axis direction of the laser may include dispersing the laser in the short-axis direction through a first concave lens, and straightly moving the laser dispersed in the short-axis direction through a first convex lens.

In the present embodiments, the decreasing of the length in the long-axis direction of the laser may include focusing the laser in the long-axis direction through a second convex lens, and straightly moving the laser focused in the long-axis direction through a second concave lens.

In the present embodiments, the emitting of the laser may include emitting a first laser, and emitting a second laser, where the converting of the laser may include converting the first laser into a first converted laser having dispersion in the long-axis direction greater than dispersion in the short-axis direction.

In the present embodiments, the converting of the laser may further include converting the second laser into a second converted laser having dispersion in the long-axis direction greater than dispersion in the short-axis direction.

In the present embodiments, the display apparatus manufacturing method may further include converting a path of the laser of the converted laser.

Other aspects, features, and advantages other than those described above will become apparent from the accompanying drawings, the appended claims, and the detailed description of the disclosure.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a schematic block diagram of a display apparatus manufacturing apparatus according to an embodiment;

FIG. 2 is a schematic perspective view of a laser emitter according to an embodiment;

FIG. 3 is a schematic side view of a laser converter according to an embodiment;

FIG. 4 is a schematic plan view of a laser converter according to an embodiment;

FIG. 5 is a schematic front view of an angle converter according to an embodiment;

FIG. 6 is a schematic perspective view of a size converter according to an embodiment;

FIGS. 7A to 7C are schematic cross-sectional views of a laser according to an embodiment;

FIG. 8 is a schematic side view of a portion of a display apparatus manufacturing apparatus according to an embodiment;

FIG. 9 is a schematic perspective view illustrating a process in which a laser is irradiated onto a display substrate according to an embodiment;

FIG. 10 is a schematic plan view of a display substrate according to an embodiment;

FIG. 11 is a plan view schematically illustrating a display apparatus manufactured by a display apparatus manufacturing method according to an embodiment;

FIG. 12 is a cross-sectional view schematically illustrating a display apparatus manufactured by a display apparatus manufacturing method according to an embodiment;

FIG. 13 is an equivalent circuit diagram illustrating a pixel according to an embodiment;

FIG. 14 is a schematic block diagram of a display apparatus manufacturing apparatus according to another embodiment;

FIG. 15 is a schematic side view of a laser converter according to another embodiment;

FIG. 16 is a schematic side view of a portion of a display apparatus manufacturing apparatus according to another embodiment;

FIG. 17 is a schematic block diagram of a display apparatus manufacturing apparatus according to another embodiment;

FIG. 18 is a schematic side view of a laser converter according to another embodiment;

FIGS. 19A to 19C are schematic cross-sectional views of a laser according to another embodiment; and

FIG. 20 is a schematic side view of a portion of a display apparatus manufacturing apparatus according to another embodiment.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects of the present description. As used herein, the term “and/or” includes any and all combinations of one or more of the associated listed items. Throughout the disclosure, the expression “at least one of a, b or c” indicates only a, only b, only c, both a and b, both a and c, both b and c, all of a, b, and c, or variations thereof.

The disclosure may include various embodiments and modifications, and certain embodiments thereof are illustrated in the drawings and will be described herein in detail. The effects and features of the disclosure and the accomplishing methods thereof will become apparent from the embodiments described below in detail with reference to the accompanying drawings. However, the disclosure is not limited to the embodiments described below and may be embodied in various modes.

Hereinafter, embodiments will be described in detail with reference to the accompanying drawings, and in the following description, like reference numerals will denote like elements and redundant descriptions thereof will be omitted for conciseness.

It will be understood that although terms such as “first” and “second” may be used herein to describe various elements, these elements should not be limited by these terms and these terms are only used to distinguish one element from another element.

As used herein, the singular forms “a,” “an,” and “the” are intended to include the plural forms as well, unless the context clearly indicates otherwise.

Also, it will be understood that the terms “comprise,” “include,” and “have” used herein specify the presence of stated features or elements, but do not preclude the presence or addition of one or more other features or elements.

It will be understood that when a layer, region, area, component, or element is referred to as being “on” another layer, region, area, component, or element, it may be “directly on” the other layer, region, area, component, or element or may be “indirectly on” the other layer, region, area, component, or element with one or more intervening layers, regions, areas, components, or elements therebetween.

Sizes of elements in the drawings may be exaggerated for convenience of description. In other words, because the sizes and thicknesses of elements in the drawings are arbitrarily illustrated for convenience of description, the disclosure is not limited thereto.

Also, herein, the x axis, the y axis, and the z axis are not limited to three axes of the rectangular coordinate system and may be interpreted in a broader sense. For example, the x axis, the y axis, and the z axis may be perpendicular to one another or may represent different directions that are not perpendicular to one another.

When a certain embodiment may be implemented differently, a particular process order may be performed differently from the described order. For example, two consecutively described processes may be performed substantially at the same time or may be performed in an order opposite to the described order.

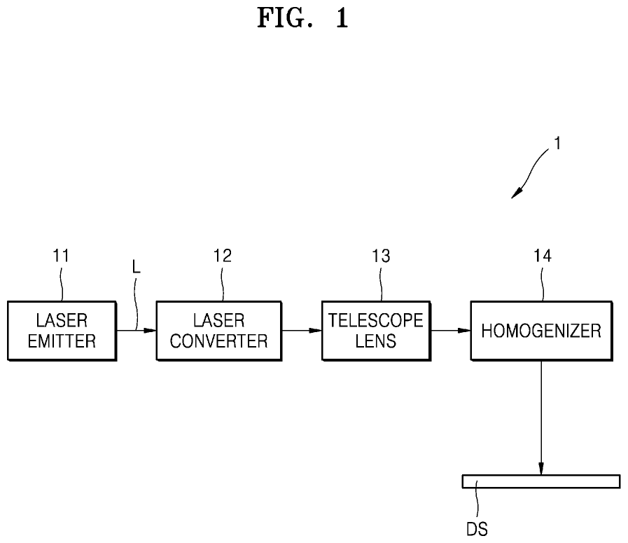

FIG. 1 is a schematic block diagram of a display apparatus manufacturing apparatus according to an embodiment.

Referring to FIG. 1, a display apparatus manufacturing apparatus 1 may include a laser emitter 11, a laser converter 12, a telescope lens 13, and a homogenizer 14.

The laser emitter 11 may emit a laser L. In the laser L emitted from the laser emitter 11, dispersion in the short-axis direction may be greater than dispersion in the long-axis direction. The laser L emitted from the laser emitter 11 may be incident on the laser converter 12.

The laser converter 12 may convert the laser L emitted from the laser emitter 11 and having dispersion in the short-axis direction greater than dispersion in the long-axis direction into a laser L having dispersion in the long-axis direction greater than dispersion in the short-axis direction. The laser L having passed through the laser converter 12 may be incident on the telescope lens 13.

The telescope lens 13 may adjust the size of a cross-section of the laser L. Here, the cross-section of the laser L may refer to a cross-section perpendicular to the propagation direction of the laser L. The telescope lens 13 may adjust at least one of a length in the long-axis direction and a length in the short-axis direction of the laser L. For example, the telescope lens 13 may increase the length of the laser L in the long-axis direction. However, this is merely an example, and the telescope lens 13 may variously adjust the size of the cross-section of the laser L according to the size of a display substrate DS. The laser L having passed through the telescope lens 13 may be incident on the homogenizer 14.

The homogenizer 14 may homogenize (i.e., make uniform) the energy density of the cross-section of the laser L. The laser L incident on the homogenizer 14 may be in the form of a beam and may have an energy density of a Gaussian distribution. For example, the energy density of a central portion of the cross-section of the laser L may be higher than the energy density of a peripheral portion of the cross-section of the laser L. In this case, the homogenizer 14 may homogenize the energy density of the Gaussian distribution of the laser L. For example, the homogenizer 14 may homogenize at least one of an energy density in the long-axis direction and an energy density in the short-axis direction of the laser L. The laser L having passed through the homogenizer 14 may be incident on the display substrate DS.

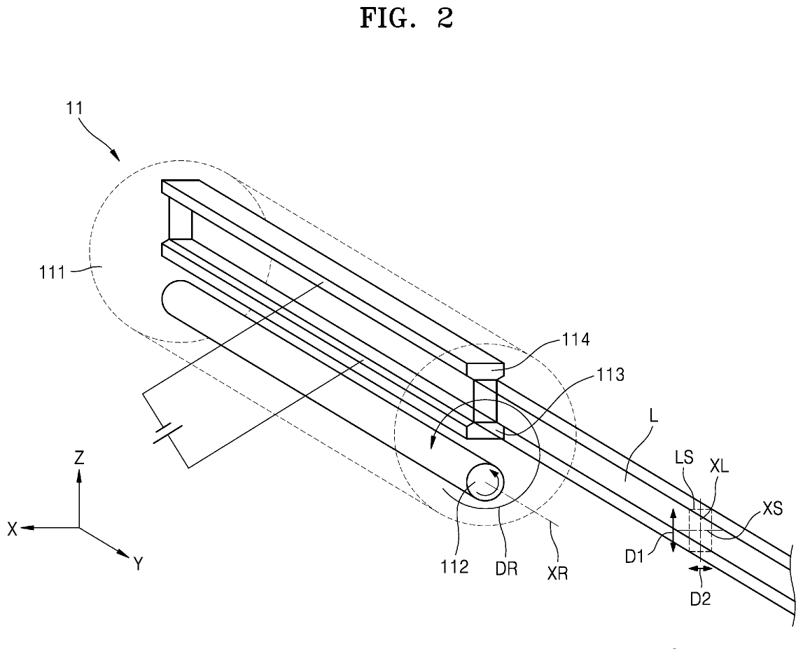

FIG. 2 is a schematic perspective view of a laser emitter according to an embodiment.

Referring to FIG. 2, the laser emitter 11 may emit an excimer laser. The laser emitter 11 may include a laser frame 111, a laser circulator 112, a first electrode 113, and a second electrode 114.

The laser frame 111 may form an external appearance of the laser emitter 11 and provide an internal space thereof. The internal space of the laser frame 111 may be filled with an excimer gas including a halogen gas for generating an excimer. For example, the excimer gas may include a fluorine (F₂) component. For example, the cross-sectional shape of the laser frame 111 may be a cylindrical shape. Thus, the excimer gas may be efficiently circulated in the internal space of the laser frame 111.

The laser circulator 112 may be arranged in the internal space of the laser frame 111 and may circulate the excimer gas filling the internal space of the laser frame 111. For example, the laser circulator 112 may include a fan structure for rotating around a rotation axis XR. In this structure, as the laser circulator 112 rotates, the excimer gas may be circulated in a circulation direction DR in the internal space of the laser frame 111. For example, the circulation direction DR may be the circumferential direction of the laser frame 111.

The first electrode 113 may be at least one of a positive electrode and a negative electrode, and the second electrode 114 may be the other one of the positive electrode and the negative electrode. For example, although FIG. 2 illustrates a case where the first electrode 113 is a positive electrode and the second electrode 114 is a negative electrode, the first electrode 113 may be a negative electrode and the second electrode 114 may be a positive electrode.

The first electrode 113 and the second electrode 114 may be arranged to face each other in the internal space of the laser frame 111. As a high voltage is applied to the first electrode 113 and the second electrode 114, a discharge area may be formed between the first electrode 113 and the second electrode 114. A laser L may be generated as the excimer gas passes through the discharge area while circulating in the internal space of the laser frame 111, and the generated laser L may be emitted through one side of the laser frame 111 (e.g., the side facing the +Y axis).

The distance between the first electrode 113 and the second electrode 114 may be greater than the width of the first electrode 113 and the second electrode 114 in X axis direction. In this structure, the laser L emitted from the laser emitter 11 may have a long axis XL and a short axis XS. Here, the long axis XL may be the long axis of a cross-section LS of the laser L, and the short axis XS may be the short axis of the cross-section LS of the laser L.

Because the excimer gas passes in the widthwise direction (e.g., X-axis direction) of the first electrode 113 and the second electrode 114 between the first electrode 113 and the second electrode 114, dispersion in a short-axis direction D2 of the laser L emitted from the laser emitter 11 may be great. Also, as the distance between the first electrode 113 and the second electrode 114 is fixed, dispersion in a long-axis direction D1 of the laser L emitted from the laser emitter 11 may be small. That is, the dispersion in the short-axis direction D2 of the laser L emitted from the laser emitter 11 may be greater than the dispersion in the long-axis direction D1.

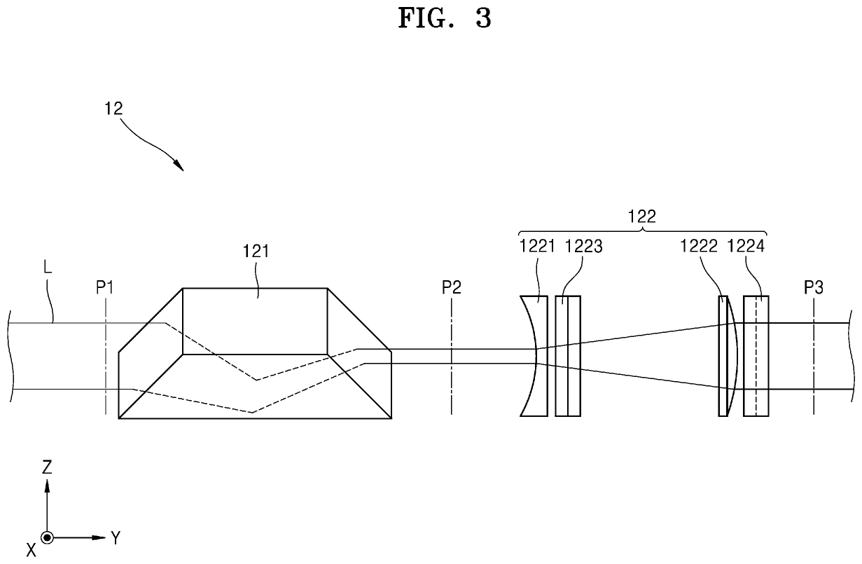

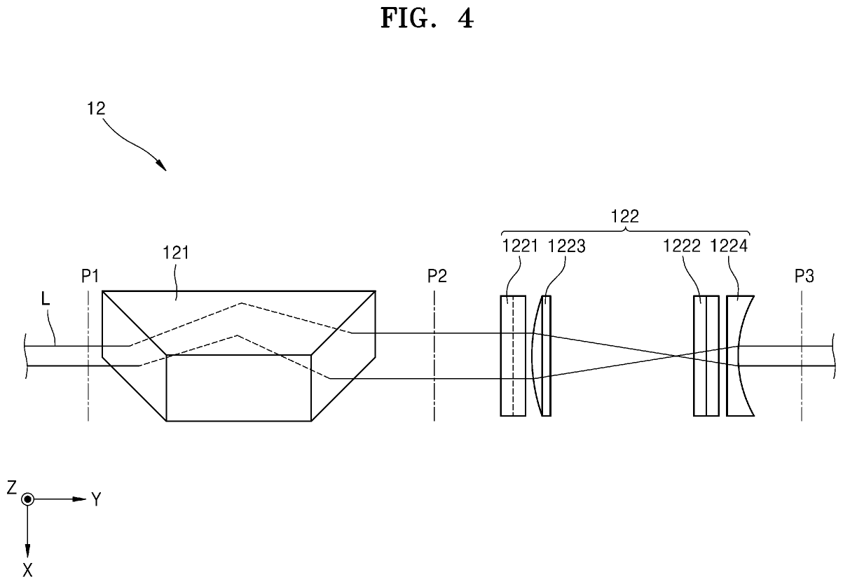

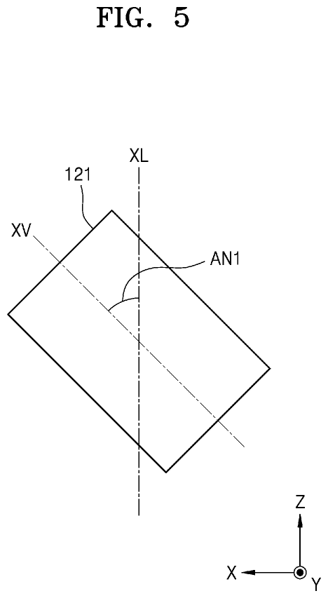

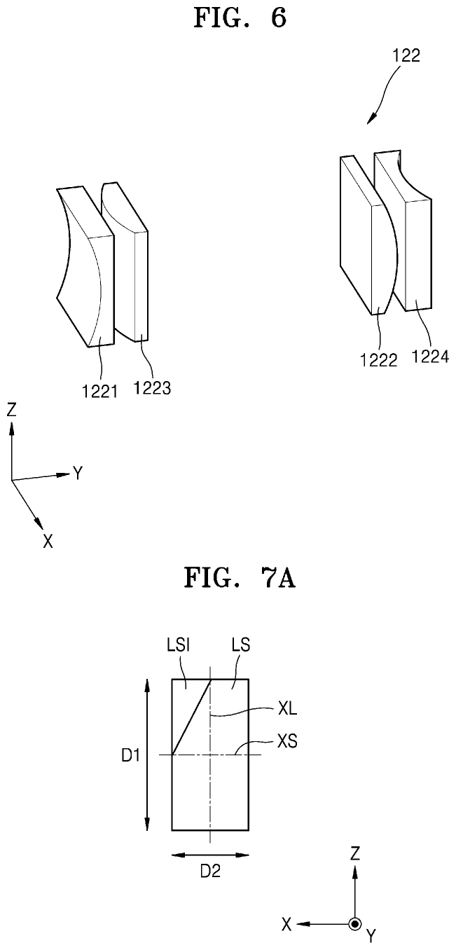

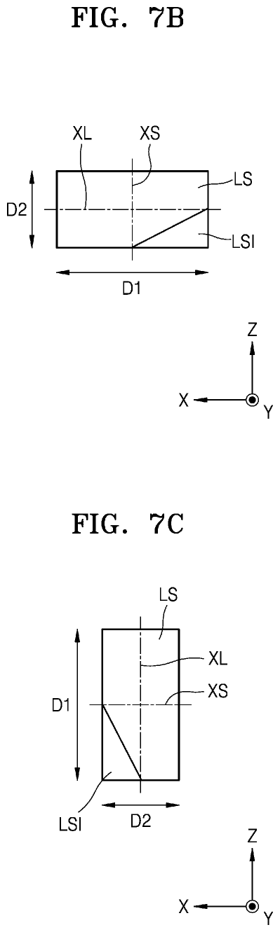

FIG. 3 is a schematic side view of a laser converter according to an embodiment, here, FIG. 3 is a view in −X-axis direction, FIG. 4 is a schematic plan view of a laser converter according to an embodiment, here, the plan view is a view in −Z-axis direction, FIG. 5 is a schematic front view of an angle converter according to an embodiment, here, the front view is a view in −Y-axis direction, FIG. 6 is a schematic perspective view of a size converter according to an embodiment, and FIGS. 7A to 7C are schematic cross-sectional views of a laser according to an embodiment.

Referring to FIGS. 3 to 7C, the laser converter 12 may convert the laser L emitted from the laser emitter 11 and having dispersion in the short-axis direction D2 greater than dispersion in the long-axis direction D1 into a laser L having dispersion in the long-axis direction D1 greater than dispersion in the short-axis direction D2. The laser converter 12 may include an angle converter 121 and a size converter 122.

The angle converter 121 may rotate the cross-section LS of the laser L. At a first position P1 in FIGS. 3 and 4, the laser L may have a long axis XL and a short axis XS as in FIG. 7A. For example, the long axis XL may be an axis parallel to the Z axis, and the short axis XS may be an axis parallel to the X axis. At the first position P1, the dispersion in the short-axis direction D2 of the laser L may be greater than the dispersion in the long-axis direction D1.

The cross-section LS of the laser L having passed through the angle converter 121 may be rotated at a second position P2 in FIGS. 3 and 4 as in FIG. 7B. For example, the laser L having passed through the angle converter 121 may be rotated by 90 degrees with respect to the propagation direction of the laser L (e.g., the +Y-axis direction) as in FIG. 7B as compared with FIG. 7A. However, even when the laser L passes through the angle converter 121, the dispersion in the short-axis direction D2 may be greater than the dispersion in the long-axis direction D1.

For example, the angle converter 121 may include a dove prism. The dove prism may be a prism having an isosceles trapezoidal cross-section parallel to the lengthwise direction (e.g., Y-axis direction) and a rectangular cross-section perpendicular to the lengthwise direction.

As in FIGS. 3 and 4, the dove prism may be arranged such that the lengthwise direction thereof may be parallel to the propagation direction of the laser L (e.g., the +Y-axis direction). Also, as in FIG. 5, the dove prism may be arranged such that a vertical axis XV thereof may form a first angle AN1 with respect to the long axis XL of the laser L incident on the angle converter 121. For example, the first angle AN1 may be 45 degrees (°).

In this structure, the laser L incident on the angle converter 121 may be rotated by twice the first angle AN1 with respect to the lengthwise direction of the dove prism after vertical inversion while passing through the dove prism. For example, when the first angle AN1 is 45 degrees, the laser L incident on the angle converter 121 may be rotated by 90 degrees with respect to the lengthwise direction (e.g., Y-axis direction) of the dove prism after vertical inversion.

Hereinafter, for convenience of description, the upper left area of the cross-section LS of the laser L at the first position P1 illustrated in FIG. 7A will be referred to as a first laser area LS1. Because the laser L at the first position P1 illustrated in FIG. 7A is rotated by 90 degrees with respect to the propagation direction of the laser L (e.g., the +Y-axis direction) after vertical inversion while passing through the dove prism, the first laser area LS1 may move to the lower right side like the cross-section LS of the laser L at the second position P2 illustrated in FIG. 7B.

As a result, while the laser L passes through the dove prism, the shape of the cross-section LS of the laser L may be rotated by 90 degrees. However, even when the laser L passes through the dove prism, the dispersion in the short-axis direction D2 may still be greater than the dispersion in the long-axis direction D1.

The size converter 122 may increase the length in the short-axis direction D2 of the laser L and decrease the length in the long-axis direction D1 of the laser L. Comparing FIG. 7B illustrating the cross-section LS of the laser L at the second position P2 in FIGS. 3 and 4 with FIG. 7C illustrating the cross-section LS of the laser L at a third position P3 in FIGS. 3 and 4, the laser L having passed through the size converter 122 may increase in length in the short-axis direction D2 and decrease in length in the long-axis direction D1. As a result, the long axis XL of the laser L before passing through the size converter 122 may be converted into the short axis XS while passing through the size converter 122, and the short axis XS of the laser L before passing through the size converter 122 may be converted into the long axis XL while passing through the size converter 122.

Referring to FIGS. 3, 4, and 5, the size converter 122 may include a first concave lens 1221, a first convex lens 1222, a second convex lens 1223, and a second concave lens 1224.

The first concave lens 1221 may include a lens having a concave shape when viewed in one direction (e.g., the X-axis direction) as in FIG. 3. The concave surface of the first concave lens 1221 may be arranged to face the propagation direction of the laser L (e.g., the +Y-axis direction). In this structure, the first concave lens 1221 may disperse the laser L in the short-axis direction D2.

The first convex lens 1222 may include a lens having a convex shape when viewed in one direction (e.g., the X-axis direction) as in FIG. 3. The convex surface of the first convex lens 1222 may be arranged to face the propagation direction of the laser L (e.g., the +Y-axis direction). In this structure, the first convex lens 1222 may straightly move the laser L dispersed in the short-axis direction D2.

The first concave lens 1221 and the first convex lens 1222 may be sequentially arranged in the propagation direction of the laser L (e.g., the +Y-axis direction). In this structure, the laser L may increase in length in the short-axis direction D2 while sequentially passing through the first concave lens 1221 and the first convex lens 1222.

The second convex lens 1223 may include a lens having a convex shape when viewed in another direction (e.g., the +Z-axis direction) as in FIG. 4. The convex surface of the second convex lens 1223 may be arranged to face the propagation direction of the laser L (e.g., the +Y-axis direction). In this structure, the second convex lens 1223 may focus the laser L in the long-axis direction D1.

The second concave lens 1224 may include a lens having a concave shape when viewed in another direction (e.g., the +Z-axis direction) as in FIG. 4. The concave surface of the second concave lens 1224 may be arranged to face the propagation direction of the laser L (e.g., the +Y-axis direction). In this structure, the second concave lens 1224 may straightly move the laser L focused in the long-axis direction D1.

The second convex lens 1223 and the second concave lens 1224 may be sequentially arranged in the propagation direction of the laser L (e.g., the +Y-axis direction). In this structure, the laser L may decrease in length in the long-axis direction D1 while sequentially passing through the second convex lens 1223 and the second concave lens 1224.

The first concave lens 1221 and the first convex lens 1222 may be required to be spaced apart from each other by a certain distance to secure a focal length. Also, the second convex lens 1223 and the second concave lens 1224 may be required to be spaced apart from each other by a certain distance to secure a focal length. The first concave lens 1221, the second convex lens 1223, the first convex lens 1222, and the second concave lens 1224 may be sequentially arranged in the propagation direction of the laser L (e.g., the +Y-axis direction). In this structure, because the first concave lens 1221 and the first convex lens 1222 share at least a portion of the focal length with the second convex lens 1223 and the second concave lens 1224, it may be advantageous for miniaturization of the size converter 122.

As described above, the cross-section LS of the laser L at the second position P2 in FIGS. 3 and 4 may have a long axis XL and a short axis XS and the first laser area LS1 may be located on the lower right side as in FIG. 7B. While the laser L passes through the size converter 122, the cross-section LS of the laser L at the third position P3 in FIGS. 3 and 4 may increase in length in the short-axis direction D2 and may decrease in length in the long-axis direction D1 as in FIG. 7C. That is, the short axis XS of the laser L before passing through the size converter 122 may be converted into the long axis XL while passing through the size converter 122. Also, the long axis XL of the laser L before passing through the size converter 122 may be converted into the short axis XS while passing through the size converter 122. As in FIG. 4, while the laser L passes through the second convex lens 1223 and the second concave lens 1224, the phase thereof may be inverted, and thus, as in FIG. 7C, the first laser area LS1 may move to the lower left side due to inversion with respect to the long axis XL.

Thus, while the laser L passes through the size converter 122, because the long axis XL is converted into the short axis XS and the short axis XS is converted into the long axis XL, the laser L having dispersion in the short-axis direction D2 greater than dispersion in the long-axis direction D1 may be converted into a laser L having dispersion in the long-axis direction D1 greater than dispersion in the short-axis direction D2.

FIG. 4 illustrates that the phase is inverted while the laser L passes through the second convex lens 1223 and the second concave lens 1224; however, this is merely an example and the phase may not be inverted depending on the distance between the second convex lens 1223 and the second concave lens 1224. In this case, the first laser area LS1 may still be located on the lower right side in FIG. 7C.

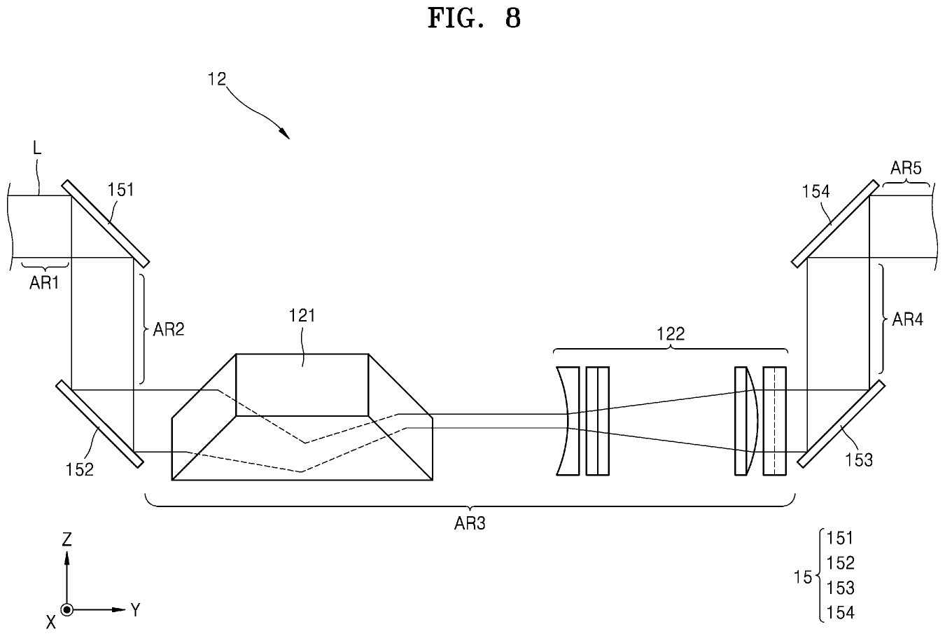

FIG. 8 is a schematic side view of a portion of a display apparatus manufacturing apparatus according to an embodiment.

Referring to FIG. 8, unlike the display apparatus manufacturing apparatus 1 described with reference to FIGS. 1 to 7C, a path converter 15 may be further included. Redundant descriptions with those provided above will be omitted for convenience of description.

The path converter 15 may convert the path of the laser L. The path converter 15 may include a flat mirror and may convert the path of the laser L by reflecting the laser L. For example, the path converter 15 may change the propagation direction of the laser L by 90 degrees. In this structure, the laser converter 12 may be freely arranged. Thus, it may be advantageous for miniaturization of the display apparatus manufacturing apparatus 1.

The path converter 15 may include a first mirror 151, a second mirror 152, a third mirror 153, and a fourth mirror 154 that reflect the laser L. Each of the first mirror 151, the second mirror 152, the third mirror 153, and the fourth mirror 154 may include a flat mirror. The laser L may be sequentially reflected by the first mirror 151, the second mirror 152, the third mirror 153, and the fourth mirror 154.

An area between the laser emitter 11 and the first mirror 151 will be referred to as a first mirror area AR1, an area between the first mirror 151 and the second mirror 152 will be referred to as a second mirror area AR2, an area between the second mirror 152 and the third mirror 153 will be referred to as a third mirror area AR3, an area between the third mirror 153 and the fourth mirror 154 will be referred to as a fourth mirror, and an area between the fourth mirror 154 and a telescope lens will be referred to as a fifth mirror area AR5.

The laser converter 12 may be arranged in at least one of the first mirror area AR1, the second mirror area AR2, the third mirror area AR3, the fourth mirror area AR4, and the fifth mirror area AR5. For example, as in FIG. 8, both the angle converter 121 and the size converter 122 may be arranged in the third mirror area AR3. However, the embodiment illustrated in FIG. 8 is merely an example, and the arrangement of the laser converter 12 is not limited thereto. For example, unlike the illustration in FIG. 8, the angle converter 121 may be arranged in the second mirror area AR2 and the size converter 122 may be arranged in the fourth mirror area AR4. Also, FIG. 8 illustrates that the laser L sequentially passes through the angle converter 121 and the size converter 122; however, unlike this, the laser converter 12 may be arranged such that the laser L may sequentially pass through the size converter 122 and the angle converter 121.

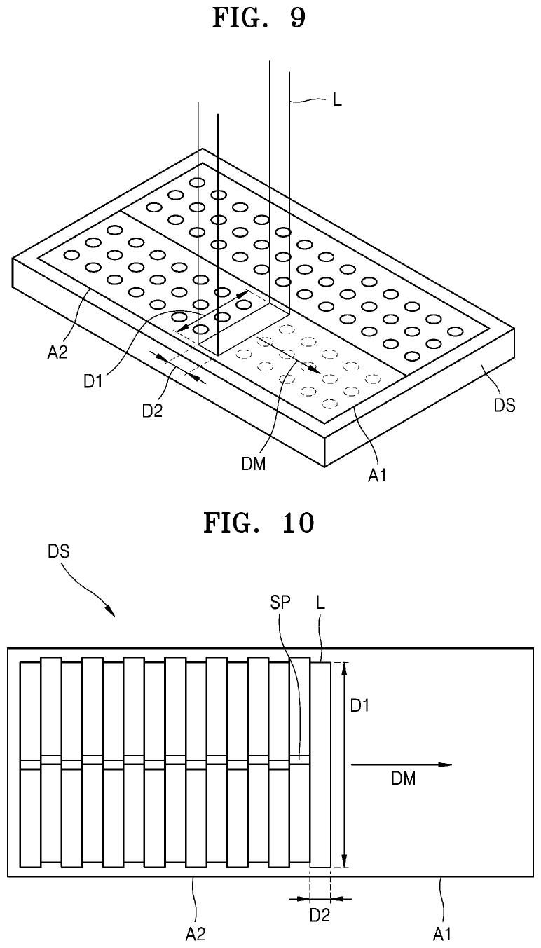

FIG. 9 is a schematic perspective view illustrating a process in which a laser is irradiated onto a display substrate according to an embodiment.

Referring to FIG. 9, the display apparatus manufacturing apparatus 1 may irradiate a laser L onto the display substrate DS. In this case, as described above, dispersion in the long-axis direction D1 of the laser L irradiated onto the display substrate DS may be greater than dispersion in the short-axis direction D2.

The laser L may be irradiated onto a first area A1 of the display substrate DS. As the laser L is irradiated onto the first area A1, the first area A1 may be crystallized and converted into a second area A2. The laser L irradiated onto the display substrate DS may move in a movement direction DM. The movement direction DM may be parallel to the short-axis direction D2 of the laser L. As the laser L moves in the movement direction DM, the second area A2 may be gradually converted into the first area A1.

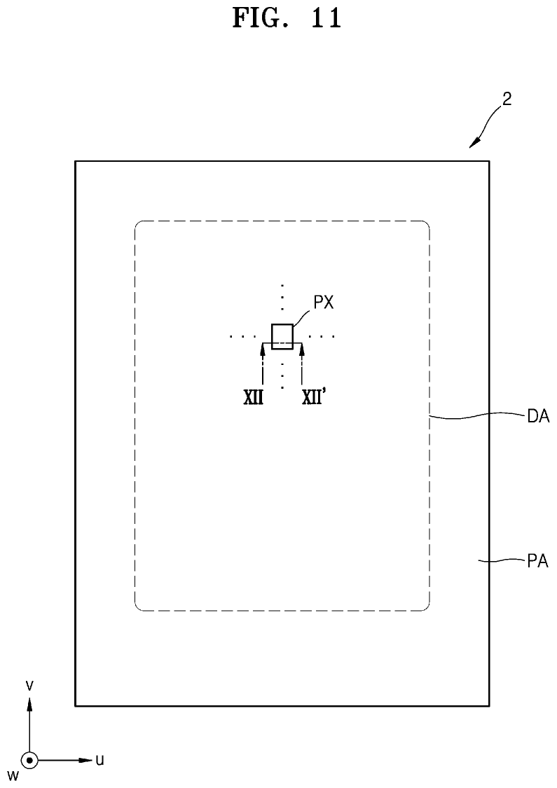

FIG. 10 is a schematic plan view of a display substrate according to an embodiment.

The movement direction DM of the laser L may be parallel to the short-axis direction D2 of the laser L. Due to small dispersion in the short-axis direction D2 of the laser L, the laser L may move at a uniform speed in the movement direction DM on the display substrate DS. Thus, it may be possible to reduce the occurrence of stripes on the display substrate DS due to the irregular movement speed of the laser L and the vibration in the short-axis direction D2.

The intensity of the irradiated laser L may not be uniform due to error factors such as dust in the display apparatus manufacturing apparatus 1 or scratches on the components. Thus, in the process in which the laser L is irradiated and thus at least a portion of the display substrate DS is crystallized, spots SP may occur on the first area A1 due to the error factors. Due to great dispersion in the long-axis direction D1 of the laser L, the spots SP occurring on the first area A1 may be dispersed in the long-axis direction D1. Thus, the visibility of spots SP in a display apparatus may decrease.

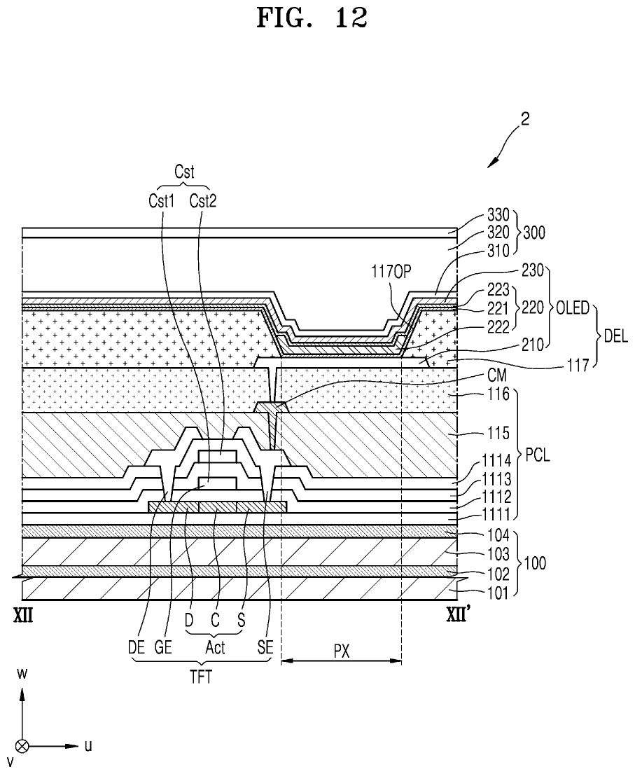

FIG. 11 is a plan view schematically illustrating a display apparatus manufactured by a display apparatus manufacturing method according to an embodiment.

Referring to FIG. 11, a display apparatus 2 manufactured according to an embodiment may include a display area DA and a peripheral area PA outside the display area DA. The display apparatus 2 may provide an image through an array of a plurality of pixels PX two-dimensionally arranged in the display area DA.

The peripheral area PA may be an area not providing an image and may entirely or partially surround the display area DA. A driver or the like for providing an electrical signal or power to a pixel circuit corresponding to each of the pixels PX may be arranged in the peripheral area PA. The peripheral area PA may include a pad that is an area to which an electronic device, a printed circuit board, or the like may be electrically connected.

Hereinafter, the display apparatus 2 will be described as including an organic light emitting diode OLED as a light emitting element; however, the display apparatus 2 of the disclosure is not limited thereto. In another embodiment, the display apparatus 2 may include a light emitting display apparatus including an inorganic light emitting diode, that is, an inorganic light emitting display apparatus. The inorganic light emitting diode may include a PN diode including inorganic semiconductor-based materials. When a voltage is applied to the PN junction diode in a forward direction, holes and electrons may be injected thereinto and energy generated by recombination of the holes and electrons may be converted into light energy to emit light of a certain color. The inorganic light emitting diode described above may have a width of several to several hundred micrometers, and in some embodiments, the inorganic light emitting diode may be referred to as a micro LED. In another embodiment, the display apparatus 2 may include a quantum dot light emitting display apparatus.

Moreover, the display apparatus 2 may be used as a display screen of various products such as televisions, notebook computers, monitors, billboards, and Internet of Things (“IoT”) apparatuses, as well as portable electronic apparatuses such as mobile phones, smart phones, tablet personal computers (PCs), mobile communication terminals, electronic notebooks, electronic books, portable multimedia players (“PMPs”), navigations, and Ultra Mobile PCs (“UMPCs”). Also, the display apparatus 2 according to an embodiment may be used in wearable devices such as smart watches, watch phones, glasses-type displays, and head-mounted displays (“HMDs”). Also, the display apparatus 2 according to an embodiment may be used as a center information display (“CID”) arranged at a vehicle's instrument panel or a vehicle's center fascia or dashboard, a room mirror display replacing a vehicle's side mirror, or a display screen arranged at a rear side of a vehicle's front seat as entertainment for a vehicle's rear seat.

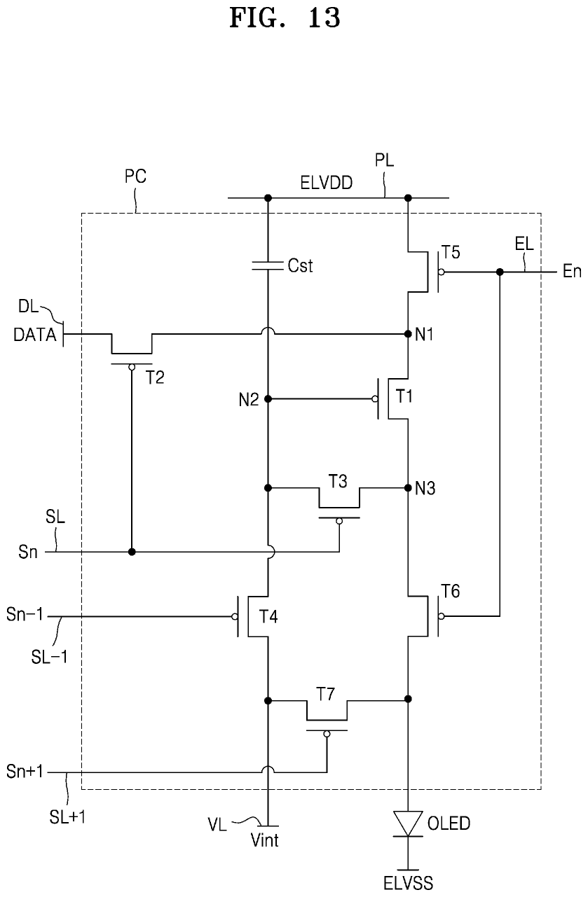

FIG. 12 is a cross-sectional view schematically illustrating a display apparatus manufactured by a display apparatus manufacturing method according to an embodiment, which may correspond to a cross-section of the display apparatus taken along line XII-XII′ of FIG. 11.

Referring to FIG. 12, the display apparatus 2 may include a stack structure of a substrate 100, a pixel circuit layer PCL, a display element layer DEL, and an encapsulation layer 300. The display substrate DS (see FIG. 10) described above may be formed in the process of manufacturing the display apparatus 2 and may include, for example, a stack of at least one of the pixel circuit layer PCL, the display element layer DEL, and the encapsulation layer 300 on the substrate 100.

The substrate 100 may have a multilayer structure including a base layer and an inorganic layer, wherein the base layer includes a polymer resin. For example, the substrate 100 may include a base layer and a barrier layer, wherein the base layer includes a polymer resin and the barrier layer includes an inorganic insulating layer. For example, the substrate 100 may include a first base layer 101, a first barrier layer 102, a second base layer 103, and a second barrier layer 104 that are sequentially stacked. The first base layer 101 and the second base layer 103 may include polyimide (“PI”), polyethersulphone (“PES”), polyarylate, polyetherimide (“PEI”), polyethylene naphthalate (“PEN”), polyethylene terephthalate (“PET”), polyphenylene sulfide (“PPS”), polycarbonate, cellulose triacetate (“TAC”), and/or cellulose acetate propionate (“CAP”). The first barrier layer 102 and the second barrier layer 104 may include an inorganic insulating material such as silicon oxide, silicon oxynitride, and/or silicon nitride. The substrate 100 may be flexible.

The pixel circuit layer PCL may be disposed over the substrate 100. FIG. 12 illustrates that the pixel circuit layer PCL includes a thin film transistor TFT, and a buffer layer 1111, a first gate insulating layer 1112, a second gate insulating layer 1113, an interlayer insulating layer 1114, a first planarization insulating layer 115, and a second planarization insulating layer 116 that are disposed under and/or over the elements of the thin film transistor TFT.

The buffer layer 1111 may reduce or block the penetration of foreign materials, moisture, or external air from under the substrate 100 and may provide a flat surface on the substrate 100. The buffer layer 1111 may include an inorganic insulating material such as silicon oxide, silicon oxynitride, or silicon nitride and may be formed in a single-layer or multilayer structure including the above material.

The thin film transistor TFT over the buffer layer 1111 may include a semiconductor layer Act, and the semiconductor layer Act may include polysilicon (poly-Si). Alternatively, the semiconductor layer Act may include amorphous silicon (a-Si), may include an oxide semiconductor, or may include an organic semiconductor or the like. The semiconductor layer Act may include a channel area C and a source area S and a drain area D arranged on opposite sides of the channel area C, respectively. A gate electrode GE may overlap the channel area C.

The display substrate DS described with reference to FIGS. 1 to 10 may include the substrate 100 and the thin film transistor TFT illustrated in FIG. 12. The laser L irradiated from the display apparatus manufacturing apparatus 1 may be irradiated onto the semiconductor layer Act. Accordingly, the poly-Si arranged in the semiconductor layer Act may be crystallized into a-Si.

The gate electrode GE may include a low-resistance metal material. The gate electrode GE may include a conductive material including molybdenum (Mo), aluminum (Al), copper (Cu), titanium (Ti), or the like and may include a single layer or multiple layers including the above material.

The first gate insulating layer 1112 between the semiconductor layer Act and the gate electrode GE may include an inorganic insulating material such as silicon oxide (SiO₂), silicon nitride (SiNₓ), silicon oxynitride (SiON), aluminum oxide (Al₂O₃), titanium oxide (TiO₂), tantalum oxide (Ta₂O₅), and hafnium oxide (HfO₂), or zinc oxide (ZnOₓ). The zinc oxide (ZnOₓ) may include zinc oxide (ZnO) and/or zinc peroxide (ZnO₂).

The second gate insulating layer 1113 may be provided to cover the gate electrode GE. Like the first gate insulating layer 1112, the second gate insulating layer 1113 may include an inorganic insulating material such as silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), or zinc oxide (ZnOₓ). The zinc oxide (ZnOₓ) may include zinc oxide (ZnO) and/or zinc peroxide (ZnO₂).

An upper electrode Cst2 of a storage capacitor Cst may be disposed over the second gate insulating layer 1113. The upper electrode Cst2 may overlap the gate electrode GE thereunder. In this case, the gate electrode GE and the upper electrode Cst2 overlapping each other with the second gate insulating layer 1113 therebetween may form the storage capacitor Cst. That is, the gate electrode CE may function as a lower electrode Cst1 of the storage capacitor Cst.

As such, the storage capacitor Cst and the thin film transistor TFT may be formed to overlap each other. In some embodiments, the storage capacitor Cst may be formed not to overlap the thin film transistor TFT.

The upper electrodes Cst2 may include aluminum (Al), platinum (Pt), palladium (Pd), silver (Ag), magnesium (Mg), gold (Au), nickel (Ni), neodymium (Nd), iridium (Ir), chromium (Cr), calcium (Ca), molybdenum (Mo), titanium (Ti), tungsten (W), and/or copper (Cu) and may include a single layer or multiple layers of the above material.

The interlayer insulating layer 1114 may cover the upper electrode Cst2. The interlayer insulating layer 1114 may include silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), or zinc oxide (ZnOₓ). The zinc oxide (ZnOₓ) may include zinc oxide (ZnO) and/or zinc peroxide (ZnO₂). The interlayer insulating layer 1114 may include a single layer or multiple layers including the above inorganic insulating material.

Each of a drain electrode DE and a source electrode SE may be located over the interlayer insulating layer 1114. The drain electrode DE and the source electrode SE may be connected to the drain area D and the source area S, respectively, through contact holes formed in the insulating layers thereunder. The drain electrode DE and the source electrode SE may include a material having high conductivity. The drain electrode DE and the source electrode SE may include a conductive material including molybdenum (Mo), aluminum (Al), copper (Cu), titanium (Ti), or the like and may include a single layer or multiple layers including the above material. In an embodiment, the drain electrode DE and the source electrode SE may have a multilayer structure of Ti/Al/Ti.

The first planarization insulating layer 115 may cover the drain electrode DE and the source electrode SE. The first planarization insulating layer 115 may include an organic insulating material such as a general-purpose polymer such as polymethylmethacrylate (“PMMA”) or polystyrene (“PS”), a polymer derivative having a phenolic group, an acrylic polymer, an imide-based polymer, an aryl ether-based polymer, an amide-based polymer, a fluorine-based polymer, a p-xylene-based polymer, a vinyl alcohol-based polymer, or any blend thereof.

The second planarization insulating layer 116 may be disposed over the first planarization insulating layer 115. The second planarization insulating layer 116 may include the same material as the first planarization insulating layer 115 and may include an organic insulating material such as a general-purpose polymer, such as polymethylmethacrylate (PMMA) or polystyrene (PS), a polymer derivative having a phenolic group, an acrylic polymer, an imide-based polymer, an aryl ether-based polymer, an amide-based polymer, a fluorine-based polymer, a p-xylene-based polymer, a vinyl alcohol-based polymer, or any blend thereof.

The display element layer DEL may be disposed over the pixel circuit layer PCL having the above structure. The display element layer DEL may include an organic light emitting diode OLED as a display element (i.e., a light emitting element), and the organic light emitting diode OLED may include a stack structure of a pixel electrode 210, an intermediate layer 220, and a common electrode 230. For example, the organic light emitting diode OLED may emit red, green, or blue light or may emit red, green, blue, or white light. The organic light emitting diode OLED may emit light through an emission area, and the emission area may be defined as a pixel PX.

The pixel electrode 210 of the organic light emitting diode OLED may be electrically connected to the thin film transistor TFT through contact holes formed in the second planarization insulating layer 116 and the first planarization insulating layer 115 and a contact metal CM disposed on the first planarization insulating layer 115.

The pixel electrode 210 may include a conductive oxide such as indium tin oxide (“ITO”), indium zinc oxide (“IZO”), zinc oxide (ZnO), indium oxide (In₂O₃), indium gallium oxide (“IGO”), or aluminum zinc oxide (“AZO”). In another embodiment, the pixel electrode 210 may include a reflective layer including silver (Ag), magnesium (Mg), aluminum (Al), platinum (Pt), palladium (Pd), gold (Au), nickel (Ni), neodymium (Nd), iridium (Ir), chromium (Cr), or any compound thereof. In another embodiment, the pixel electrode 210 may further include a layer formed of ITO, IZO, ZnO, or In₂O₃ over/under the reflective layer.

A pixel definition layer 117 including an opening 1170P exposing a center portion of the pixel electrode 210 may be disposed over the pixel electrode 210. The pixel definition layer 117 may include an organic insulating material and/or an inorganic insulating material. The opening 1170P may define an emission area of light emitted from the organic light emitting diode OLED. For example, the size/width of the opening 1170P may correspond to the size/width of the emission area. Thus, the size and/or width of the pixel PX may depend on the size and/or width of the opening 1170P of the pixel definition layer 117 corresponding thereto.

The intermediate layer 220 may include an emission layer 222 formed to correspond to the pixel electrode 210. The emission layer 222 may include a high-molecular or low-molecular weight organic material for emitting light of a certain color. Alternatively, the emission layer 222 may include an inorganic light emitting material or may include quantum dots.

In an embodiment, the intermediate layer 220 may include a first functional layer 221 and a second functional layer 223 disposed under and over the emission layer 222, respectively. The first functional layer 221 may include, for example, a hole transport layer (“HTL”) or may include an HTL and a hole injection layer (“HIL”). The second functional layer 223 may be a component disposed over the emission layer 222 and may include an electron transport layer (“ETL”) and/or an electron injection layer (“EIL”). Like the common electrode 230 described below, the first functional layer 221 and/or the second functional layer 223 may be a common layer formed to entirely cover the substrate 100.

The common electrode 230 may be disposed over the pixel electrode 210 and may overlap the pixel electrode 210. The common electrode 230 may include a conductive material having a low work function. For example, the common electrode 230 may include a (semi)transparent layer including silver (Ag), magnesium (Mg), aluminum (Al), platinum (Pt), palladium (Pd), gold (Au), nickel (Ni), neodymium (Nd), iridium (Ir), chromium (Cr), lithium (Li), calcium (Ca), or any alloy thereof. Alternatively, the common electrode 230 may further include a layer such as ITO, IZO, ZnO, or In₂O₃ over the (semi)transparent layer including the above material. The common electrode 230 may be integrally formed to entirely cover the substrate 100.

The encapsulation layer 300 may be disposed over the display element layer DEL and may cover the display element layer DEL. The encapsulation layer 300 may include at least one inorganic encapsulation layer and at least one organic encapsulation layer, and in an embodiment, FIG. 12 illustrates that the encapsulation layer 300 includes a first inorganic encapsulation layer 310, an organic encapsulation layer 320, and a second inorganic encapsulation layer 330 that are sequentially stacked.

The first inorganic encapsulation layer 310 and the second inorganic encapsulation layer 330 may include one or more inorganic materials among aluminum oxide, titanium oxide, tantalum oxide, hafnium oxide, zinc oxide, silicon oxide, silicon nitride, and silicon oxynitride. The organic encapsulation layer 320 may include a polymer-based material. The polymer-based material may include acryl-based resin, epoxy-based resin, polyimide, polyethylene, and the like. In an embodiment, the organic encapsulation layer 320 may include acrylate. The organic encapsulation layer 320 may be formed by curing a monomer or applying a polymer. The organic encapsulation layer 320 may be transparent.

Although not illustrated, a touch sensor layer may be disposed over the encapsulation layer 300, and an optical functional layer may be disposed over the touch sensor layer. The touch sensor layer may be configured to obtain coordinate information according to an external input, for example, a touch event. The optical functional layer may reduce the reflectance of light (external light) incident from the outside toward the display apparatus and/or may improve the color purity of light emitted from the display apparatus. In an embodiment, the optical functional layer may include a phase retarder and/or a polarizer. The phase retarder may be a film type or a liquid crystal coating type and may include a λ/2 phase retarder and/or a λ/4 phase retarder. The polarizer may also be a film type or a liquid crystal coating type. The film type may include a stretched synthetic resin film, and the liquid crystal coating type may include liquid crystals arranged in a certain arrangement. The phase retarder and the polarizer may further include a protection film.

An adhesive member may be arranged between the touch sensor layer and the optical functional layer. The adhesive member may include a general one known in the art, without limitation. The adhesive member may include a pressure sensitive adhesive (“PSA”).

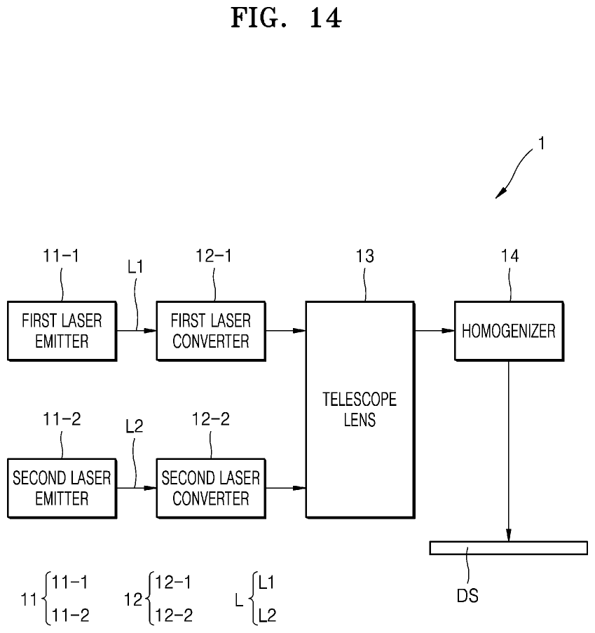

FIG. 13 is an equivalent circuit diagram illustrating a pixel according to an embodiment.

Referring to FIG. 13, a pixel circuit PC may include first to seventh transistors T1 to T7, and depending on the transistor type (p-type or n-type) and/or the operation condition, a first terminal of each of the first to seventh transistors T1 to T7 may be a source terminal or a drain terminal and a second terminal thereof may be a terminal different from the first terminal. For example, when the first terminal is a source terminal, the second terminal may be a drain terminal.

The pixel circuit PC may include a first scan line SL configured to transmit a first scan signal Sn thereto, a second scan line SL−1 configured to transmit a second scan signal Sn−1 thereto, a third scan line SL+1 configured to transmit a third scan signal Sn+1 thereto, an emission control line EL configured to transmit an emission control signal En thereto, a data line DL configured to transmit a data signal DATA, a driving voltage line PL configured to transmit a driving voltage ELVDD thereto, and an initialization voltage line VL configured to transmit an initialization voltage Vint thereto.

The first transistor T1 may include a gate terminal connected to a second node N2, a first terminal connected to a first node N1, and a second terminal connected to a third node N3. The first transistor T1 may function as a driving transistor and may receive the data signal DATA according to a switching operation of the second transistor T2 to supply a driving current to a light emitting element. The light emitting element may be an organic light emitting diode OLED.

The second transistor T2 (switching transistor) may include a gate terminal connected to the first scan line SL, a first terminal connected to the data line DL, and a second terminal connected to the first node N1 (or the first terminal of the first transistor T1). The second transistor T2 may perform a switching operation of being turned on according to the first scan signal Sn received through the first scan line SL, to transmit the data signal DATA received through the data line DL to the first node N1.

The third transistor T3 (compensation transistor) may include a gate terminal connected to the first scan line SL, a first terminal connected to the second node N2 (or the gate terminal of the first transistor T1), and a second terminal connected to the third node N3 (or the second terminal of the first transistor T1). The third transistor T3 may be turned on according to the first scan signal Sn received through the first scan line SL, to diode-connect the first transistor T1. The third transistor T3 may have a structure in which two or more transistors are connected in series.

The fourth transistor T4 (first initialization transistor) may include a gate terminal connected to the second scan line SL−1, a first terminal connected to the initialization voltage line VL, and a second terminal connected to the second node N2. The fourth transistor T4 may be turned on according to the second scan signal Sn−1 received through the second scan line SL−1, to transmit the initialization voltage Vint to the gate terminal of the first transistor T1 to initialize the gate voltage of the first transistor T1. The fourth transistor T4 may have a structure in which two or more transistors are connected in series.

The fifth transistor T5 (first emission control transistor) may include a gate terminal connected to the emission control line EL, a first terminal connected to the driving voltage line PL, and a second terminal connected to the first node N1. The sixth transistor T6 (second emission control transistor) may include a gate terminal connected to the emission control line EL, a first terminal connected to the third node N3, and a second terminal connected to a pixel electrode of the organic light emitting diode OLED. The fifth transistor T5 and the sixth transistor T6 may be simultaneously turned on according to the emission control signal En received through the emission control line EL and thus a driving current may flow through the organic light emitting diode OLED.

The seventh transistor T7 (second initialization transistor) may include a gate terminal connected to the third scan line SL+1, a first terminal connected to the second terminal of the sixth transistor T6 and the pixel electrode of the organic light emitting diode OLED, and a second terminal connected to the initialization voltage line VL. The seventh transistor T7 may be turned on according to the third scan signal Sn+1 received through the third scan line SL+1, to transmit the initialization voltage Vint to the pixel electrode of the organic light emitting diode OLED to initialize the voltage of the pixel electrode of the organic light emitting diode OLED. The seventh transistor T7 may be omitted.

A storage capacitor Cst may include a first electrode connected to the second node N2 and a second electrode connected to the driving voltage line PL.

The organic light emitting diode OLED may include the pixel electrode and an opposite electrode facing the pixel electrode, and the opposite electrode may receive a common voltage ELVSS. The organic light emitting diode OLED may receive a driving current from the first transistor T1 to emit light of a certain color to display an image. The opposite electrode thereof may be commonly, that is, integrally, provided to a plurality of pixels.

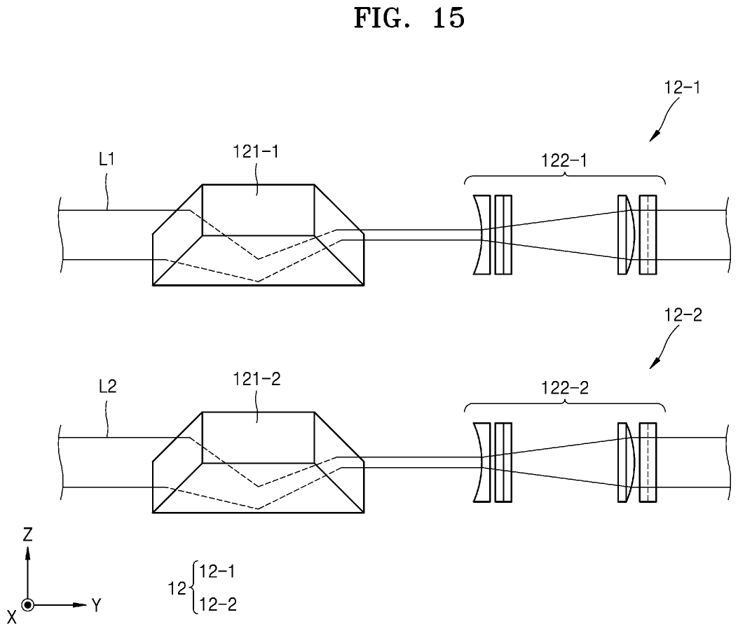

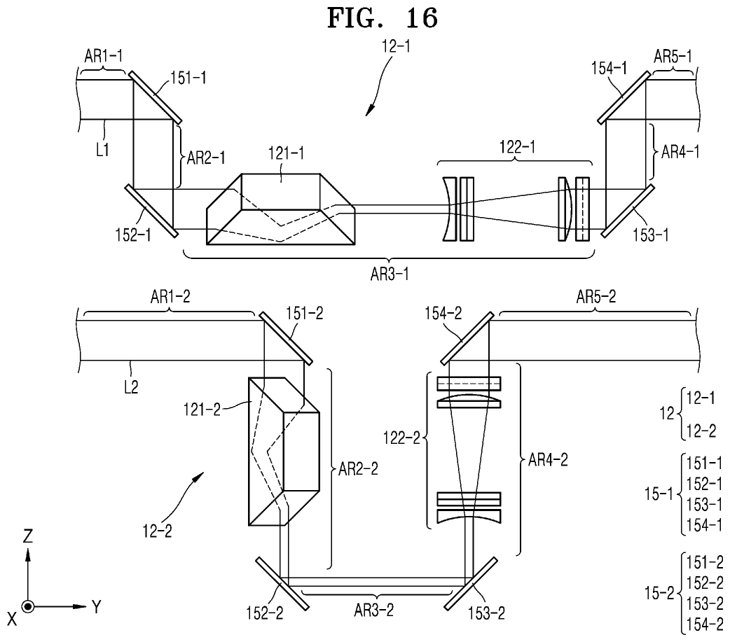

FIG. 14 is a schematic block diagram of a display apparatus manufacturing apparatus according to another embodiment, and FIG. 15 is a schematic side view of a laser converter according to another embodiment.

Referring to FIGS. 14 and 15, a display apparatus manufacturing apparatus 1 may include a laser emitter 11, a laser converter 12, a telescope lens 13, and a homogenizer 14. Redundant descriptions with those provided above will be omitted for convenience of description.

Unlike the embodiment described with reference to FIGS. 1 to 8, the laser emitter 11 may include a first laser emitter 11-1 and a second laser emitter 11-2, and the laser converter 12 may include a first laser converter 12-1 and a second laser converter 12-2. Also, the first laser converter 12-1 may include a first angle converter 121-1 and a first size converter 122-1, and the second laser converter 12-2 may include a second angle converter 121-2 and a second size converter 122-2.

A first laser L1 emitted from the first laser emitter 11-1 may be irradiated onto a display substrate DS by sequentially passing through the first laser converter 12-1, the telescope lens 13, and the homogenizer 14. Also, a second laser L2 emitted from the second laser emitter 11-2 may be irradiated onto the display substrate DS by sequentially passing through the second laser converter 12-2, the telescope lens 13, and the homogenizer 14.

The first laser L1 and the second laser L2 may overlap with each other before being irradiated onto the display substrate DS. For example, the first laser L1 and the second laser L2 may overlap with each other in the process of passing through the telescope lens 13. However, this is merely an example, and the overlapping method of the first laser L1 and the second laser L2 is not limited thereto. For example, the display apparatus manufacturing apparatus 1 may further include a separate overlapping unit for overlapping the first laser L1 and the second laser L2 with each other. In this case, the overlapping unit may be arranged in at least one location among a location between the laser converter 12 and the telescope lens 13, a location between the telescope lens 13 and the homogenizer 14, and a location between the homogenizer 14 and the display substrate DS.

In this structure, by overlapping the first laser L1 and the second laser L2 with each other and irradiating the overlapped laser onto the display substrate DS, the intensity of the laser L irradiated onto the display substrate DS may be increased.

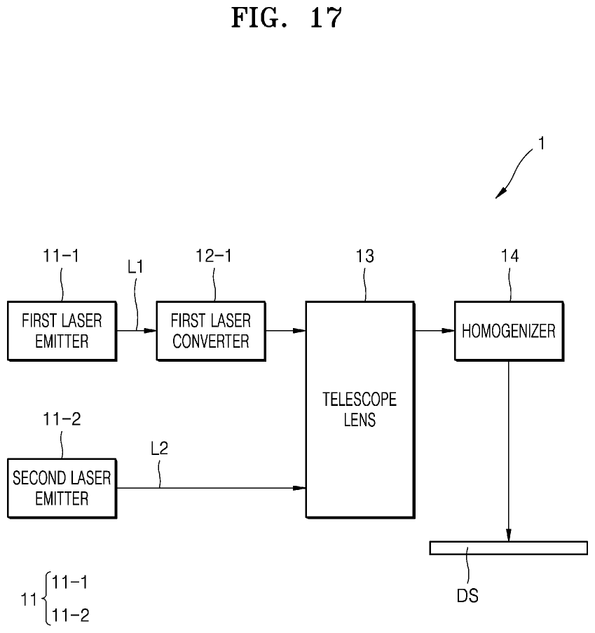

FIG. 16 is a schematic side view of a portion of a display apparatus manufacturing apparatus according to another embodiment.

Referring to FIG. 16, unlike the display apparatus manufacturing apparatus 1 described with reference to FIGS. 14 and 15, a path converter 15 may be further included. Redundant descriptions with those provided above will be omitted for convenience of description.

The path converter 15 may include a first path converter 15-1 for converting the path of a first laser L1 and a second path converter 15-2 for converting the path of a second laser L2.

The first path converter 15-1 may include a (1-1)th mirror 151-1, a (2-1)th mirror 152-1, a (3-1)th mirror 153-1, and a (4-1)th mirror 154-1 that reflect the first laser L1. The first laser L1 may be sequentially reflected by the (1-1)th mirror 151-1, the (2-1)th mirror 152-1, the (3-1)th mirror 153-1, and the (4-1)th mirror 154-1.

An area between the first laser emitter 11-1 and the (1-1)th mirror 151-1 will be referred to as a (1-1)th mirror area AR1-1, an area between the (1-1)th mirror 151-1 and the (2-1)th mirror 152-1 will be referred to as a (2-1)th mirror area AR2-1, an area between the (2-1)th mirror 152-1 and the (3-1)th mirror 153-1 will be referred to as a (3-1)th mirror area AR3-1, an area between the (3-1)th mirror 153-1 and the (4-1)th mirror 154-1 will be referred to as a (4-1)th mirror area AR4-1, and an area between the (4-1)th mirror 154-1 and a telescope lens will be referred to as a (5-1)th mirror area AR5-1.

A first laser converter 12-1 may be arranged in at least one of the (1-1)th mirror area AR1-1, the (2-1)th mirror area AR2-1, the (3-1)th mirror area AR3-1, the (4-1)th mirror area AR4-1, and the (5-1)th mirror area AR5-1. For example, as in FIG. 16, both a first angle converter 121-1 and a first size converter 122-1 may be arranged in the (3-1)th mirror area AR3-1. However, the embodiment illustrated in FIG. 16 is merely an example, and the arrangement of the first laser converter 12-1 is not limited thereto.

The second path converter 15-2 may include a (1-2)th mirror 151-2, a (2-2)th mirror 152-2, a (3-2)th mirror 153-2, and a (4-2)th mirror 154-2 that reflect the second laser L2. The second laser L2 may be sequentially reflected by the (1-2)th mirror 151-2, the (2-2)th mirror 152-2, the (3-2)th mirror 153-2, and the (4-2)th mirror 154-2.

An area between the second laser emitter 11-2 and the (1-2)th mirror 151-2 will be referred to as a (1-2)th mirror area AR1-2, an area between the (1-2)th mirror 151-2 and the (2-2)th mirror 152-2 will be referred to as a (2-2)th mirror area AR2-2, an area between the (2-2)th mirror 152-2 and the (3-2)th mirror 153-2 will be referred to as a (3-2)th mirror area AR3-2, an area between the (3-2)th mirror 153-2 and the (4-2)th mirror 154-2 will be referred to as a (4-2)th mirror area AR4-2, and an area between the (4-2)th mirror 154-2 and a telescope lens will be referred to as a (5-2)th mirror area AR5-2.

A second laser converter 12-2 may be arranged in at least one of the (1-2)th mirror area AR1-2, the (2-2)th mirror area AR2-2, the (3-2)th mirror area AR3-2, the (4-2)th mirror area AR4-2, and the (5-2)th mirror area AR5-2. For example, as in FIG. 16, a second angle converter 121-2 may be arranged in the (2-2)th mirror area AR2-2, and a second size converter 122-2 may be arranged in the (4-2)th mirror area AR4-2. However, the embodiment illustrated in FIG. 16 is merely an example, and the arrangement of the second laser converter 12-2 is not limited thereto.

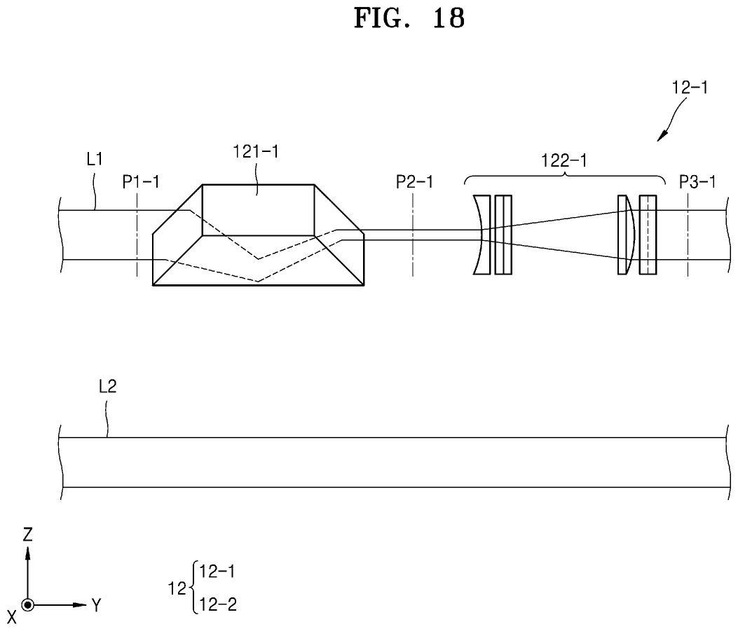

FIG. 17 is a schematic block diagram of a display apparatus manufacturing apparatus according to another embodiment.

Unlike the embodiment described with reference to FIGS. 14 to 16, a display apparatus manufacturing apparatus 1 may not include the second laser converter 12-2.

In this structure, a first laser L1 emitted from the first laser emitter 11-1 may be irradiated onto the display substrate DS by sequentially passing through the first laser converter 12-1, the telescope lens 13, and the homogenizer 14. Also, a second laser L2 emitted from the second laser emitter 11-2 may be irradiated onto the display substrate DS by sequentially passing through the telescope lens 13 and the homogenizer 14. The first laser L1 and the second laser L2 may overlap with each other before being irradiated onto the display substrate DS.

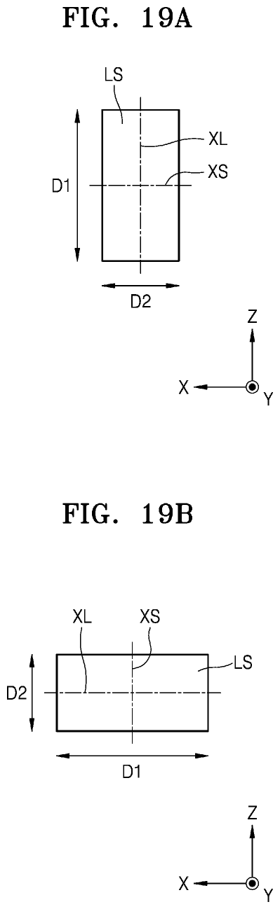

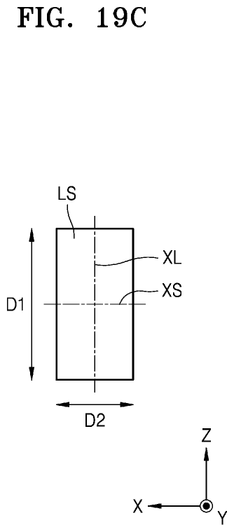

FIG. 18 is a schematic side view of a laser converter according to another embodiment, and FIGS. 19A to 19C are schematic cross-sectional views of a laser according to another embodiment.

A first laser converter 12-1 may include a first angle converter 121-1 and a first size converter 122-1. Redundant descriptions with those provided above will be omitted for convenience of description.

At a (1-1)th position P1-1 in FIG. 18, a cross-section LS of a first laser L1 may have a long axis XL and a short axis XS as in FIG. 19A. For convenience of description, it is assumed that a polarization ratio in the long-axis direction D1 of the first laser L1 is 57% and a polarization ratio in the short-axis direction D2 is 43%.

While the first laser L1 passes through the first angle converter 121-1, the cross-section LS of the first laser L1 may be rotated by 90 degrees with respect to the propagation direction of the first laser L1 (e.g., the +Y-axis direction) at a (2-1)th position P2-1 in FIG. 18 as in FIG. 19B. However, even when the first laser L1 passes through the first angle converter 121-1, the polarization ratio in the long-axis direction D1 may still be 57% and the polarization ratio in the short-axis direction D2 may still be 43%.

While the first laser L1 passes through the first size converter 122-1, the cross-section LS of the first laser L1 at a (3-1)th position P3-1 in FIG. 18 may increase in length in the short-axis direction D2 and may decrease in length in the long-axis direction D1 as in FIG. 19C. As a result, as the first laser L1 passes through the first size converter 122-1, the long axis XL may be converted into the short axis XS and the short axis XS may be converted into the long axis XL. Thus, in the first laser L1, the polarization ratio in the long-axis direction D1 may be converted from 57% to 43%, and the polarization ratio in the short-axis direction D2 may be converted from 43% to 57%.

The polarization ratio of the second laser L2 emitted from the second laser emitter 11-2 may be equal to the polarization ratio of the first laser L1 emitted from the first laser emitter 11-1. Because the second laser L2 emitted from the second laser emitter 11-2 does not pass through a separate laser converter, the cross-sectional shape illustrated in FIG. 19A may be maintained and thus the polarization ratio thereof may also be maintained. Thus, the polarization ratio in the long-axis direction D1 of the first laser L1 may be maintained at 57% and the polarization ratio in the short-axis direction D2 may be maintained at 43%.

The first laser L1 having a polarization ratio of 43% in the long-axis direction D1 and a polarization ratio of 57% in the short-axis direction D2 and the second laser L2 having a polarization ratio of 57% in the long-axis direction D1 and a polarization ratio of 43% in the short-axis direction D2 may overlap with each other. As a result, because the first laser L1 and the second laser L2 overlap with each other, a laser L having a polarization ratio of 50% in the long-axis direction D1 and a polarization ratio of 50% in the short-axis direction D2 may be irradiated onto the display substrate DS. Thus, in the process in which at least a portion of the display substrate DS is crystallized, the grain size and the alignment degree of particles on the display substrate DS may be uniform. For example, the particles on the display substrate DS may include at least one component among poly-Si and a-Si.

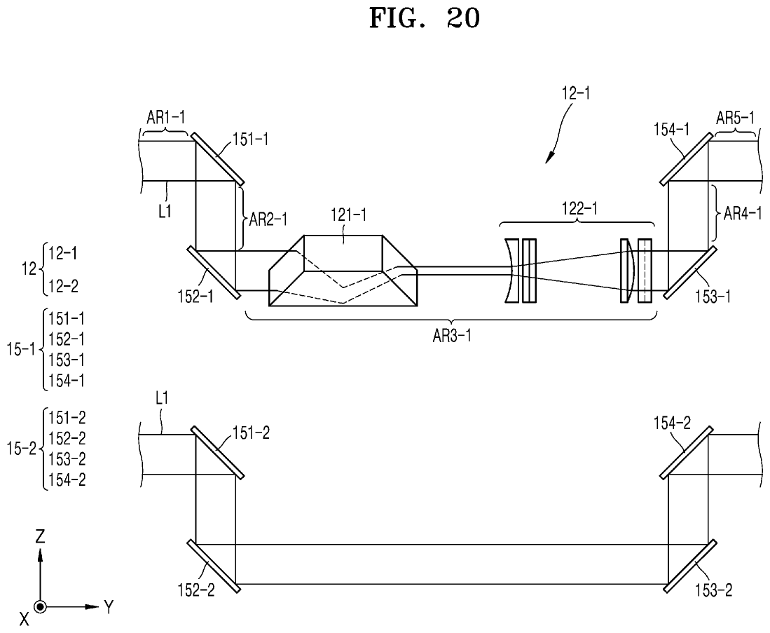

FIG. 20 is a schematic side view of a portion of a display apparatus manufacturing apparatus according to another embodiment.

Referring to FIG. 20, unlike the display apparatus manufacturing apparatus 1 described with reference to FIGS. 17 to 19C, a path converter 15 may be further included. Redundant descriptions with those provided above will be omitted for convenience of description.

The path converter 15 may include a first path converter 15-1 for converting the path of a first laser L1 and a second path converter 15-2 for converting the path of a second laser L2.

The first path converter 15-1 may include a (1-1)th mirror 151-1, a (2-1)th mirror 152-1, a (3-1)th mirror 153-1, and a (4-1)th mirror 154-1 that reflect the first laser L1. The first laser L1 may be sequentially reflected by the (1-1)th mirror 151-1, the (2-1)th mirror 152-1, the (3-1)th mirror 153-1, and the (4-1)th mirror 154-1.

An area between the first laser emitter 11-1 and the (1-1)th mirror 151-1 will be referred to as a (1-1)th mirror area AR1-1, an area between the (1-1)th mirror 151-1 and the (2-1)th mirror 152-1 will be referred to as a (2-1)th mirror area AR2-1, an area between the (2-1)th mirror 152-1 and the (3-1)th mirror 153-1 will be referred to as a (3-1)th mirror area AR3-1, an area between the (3-1)th mirror 153-1 and the (4-1)th mirror 154-1 will be referred to as a (4-1)th mirror area AR4-1, and an area between the (4-1)th mirror 154-1 and a telescope lens will be referred to as a (5-1)th mirror area AR5-1.

A first laser converter 12-1 may be arranged in at least one of the (1-1)th mirror area AR1-1, the (2-1)th mirror area AR2-1, the (3-1)th mirror area AR3-1, the (4-1)th mirror area AR4-1, and the (5-1)th mirror area AR5-1. For example, as in FIG. 16, both a first angle converter 121-1 and a first size converter 122-1 may be arranged in the (3-1)th mirror area AR3-1. However, the embodiment illustrated in FIG. 20 is merely an example, and the arrangement of the first laser converter 12-1 is not limited thereto.

The second path converter 15-2 may include a (1-2)th mirror 151-2, a (2-2)th mirror 152-2, a (3-2)th mirror 153-2, and a (4-2)th mirror 154-2 that reflect the second laser L2. The second laser L2 may be sequentially reflected by the (1-2)th mirror 151-2, the (2-2)th mirror 152-2, the (3-2)th mirror 153-2, and the (4-2)th mirror 154-2.

According to embodiments, it may be possible to effectively reduce the occurrence of stripes on the display substrate due to the irregular movement speed of the laser and the vibration in the short-axis direction in the process of crystallizing at least a portion of the display substrate. Also, the visibility of spots may be reduced by dispersing the spots occurring on the display substrate in the long-axis direction.

Effects of the disclosure are not limited to the effects described above, and other effects not described herein will be clearly understood by those of ordinary skill in the art from the description of the claims.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A display apparatus manufacturing apparatus comprising:
a laser emitter, which emits a laser having dispersion in a short-axis direction greater than dispersion in a long-axis direction; and
a laser converter, which converts the laser into a converted laser having dispersion in the long-axis direction greater than dispersion in the short-axis direction.

2. The display apparatus manufacturing apparatus of claim 1, wherein the laser converter comprises an angle converter, which rotates a cross-section of the laser.

3. The display apparatus manufacturing apparatus of claim 2, wherein the angle converter comprises a dove prism.

4. The display apparatus manufacturing apparatus of claim 1, wherein the laser converter comprises a size converter, which increases a length in the short-axis direction of the laser and decreases a length in the long-axis direction of the laser.

5. The display apparatus manufacturing apparatus of claim 4, wherein the size converter comprises:
a first concave lens, which disperses the laser in the short-axis direction; and
a first convex lens, which straightly moves the laser dispersed in the short-axis direction,
wherein the laser increases in the length in the short-axis direction while sequentially passing through the first concave lens and the first convex lens.

6. The display apparatus manufacturing apparatus of claim 4, wherein the size converter comprises:
a second convex lens, which focuses the laser in the long-axis direction; and
a second concave lens, which straightly moves the laser focused in the long-axis direction,
wherein the laser decreases in the length in the long-axis direction while sequentially passing through the second convex lens and the second concave lens.

7. The display apparatus manufacturing apparatus of claim 1, wherein the laser emitter comprises:
a first laser emitter, which emits a first laser; and
a second laser emitter, which emits a second laser,
wherein the laser converter comprises a first laser converter through which the first laser passes.

8. The display apparatus manufacturing apparatus of claim 7, wherein the laser converter further comprises a second laser converter through which the second laser passes.

9. The display apparatus manufacturing apparatus of claim 1, further comprising a path converter, which converts a path of the laser or the converted laser.

10. The display apparatus manufacturing apparatus of claim 1, further comprising a telescope lens, which adjusts a size of a cross-section of the converted laser.

11. The display apparatus manufacturing apparatus of claim 1, further comprising a homogenizer, which homogenizes an energy density of a cross-section of the converted laser.

12. A display apparatus manufacturing method comprising:
emitting a laser having dispersion in a short-axis direction greater than dispersion in a long-axis direction;
converting the laser into a converted laser having dispersion in the long-axis direction greater than dispersion in the short-axis direction; and
irradiating the converted laser onto a display substrate to crystallize at least a portion of the display substrate.

13. The display apparatus manufacturing method of claim 12, further comprising:
rotating a cross-section of the laser.

14. The display apparatus manufacturing method of claim 13, wherein the rotating of the cross-section of the laser comprises passing the laser through a dove prism.

15. The display apparatus manufacturing method of claim 12, further comprising:
increasing a length in the short-axis direction of the laser; and
decreasing a length in the long-axis direction of the laser.

16. The display apparatus manufacturing method of claim 15, wherein the increasing of the length in the short-axis direction of the laser comprises:
dispersing the laser in the short-axis direction through a first concave lens; and
straightly moving the laser dispersed in the short-axis direction through a first convex lens.

17. The display apparatus manufacturing method of claim 15, wherein the decreasing of the length in the long-axis direction of the laser comprises:
focusing the laser in the long-axis direction through a second convex lens; and
straightly moving the laser focused in the long-axis direction through a second concave lens.

18. The display apparatus manufacturing method of claim 12, wherein the emitting of the laser comprises:
emitting a first laser; and
emitting a second laser,
wherein the converting the laser comprises converting the first laser into a first converted laser having dispersion in the long-axis direction greater than dispersion in the short-axis direction.

19. The display apparatus manufacturing method of claim 18, wherein the converting of the laser further comprises converting the second laser into a second converted laser having dispersion in the long-axis direction greater than dispersion in the short-axis direction.

20. The display apparatus manufacturing method of claim 12, further comprising converting a path of the laser or the converted laser.
